(19) United States
(12) Patent Application Publication
(10) Pub. No.: US 2026/0116071 A1
(43) Pub. Date: Apr. 30, 2026

(54) METHOD OF MANUFACTURING LIQUID EJECTION HEAD, AND LIQUID EJECTION HEAD

(71) Applicant: CANON KABUSHIKI KAISHA, Tokyo (JP)

(72) Inventors: Satoshi TSUTSUI, Kanagawa (JP); Yohei HAMADE, Tokyo (JP); Haruka YAMAJI, Tokyo (JP); Erika KOBATAKE, Kanagawa (JP)

(21) Appl. No.: 19/361,260

(22) Filed: Oct. 17, 2025

(30) Foreign Application Priority Data
Oct. 25, 2024 (JP) 2024-188172

(51) Int. Cl. B41J 2/16; G03F 7/004; G03F 7/038

(52) U.S. Cl. CPC B41J 2/1631; B41J 2/1623; B41J 2/1645; B41J 2/1646; G03F 7/0042; G03F 7/0385

(57) ABSTRACT

A method of manufacturing a liquid ejection head including, on a substrate, an ejection port formation member and a flow path formation member includes: forming and exposing a layer of a photosensitive resin composition (1) forming the flow path formation member on the substrate; laminating and exposing a layer of a photosensitive resin composition (2) forming the ejection port formation member on the layer of the photosensitive resin composition (1); and removing unexposed portions to form the flow path formation member and the ejection port formation member, the photosensitive resin composition (1) containing a specific epoxy resin and a specific gallate-based photoacid generator.

### BACKGROUND

### Field of the Technology

The present disclosure relates to a method of manufacturing a liquid ejection head, and a liquid ejection head.

### Description of the Related Art

A liquid ejection head for discharging a liquid is used in a liquid ejection device such as an inkjet recording device, and includes, for example, an ejection port formation member, a flow path formation member, and a substrate. The flow path formation member is provided on the substrate and forms a liquid flow path and, in some cases, a liquid ejection port. A liquid supply port is formed on the substrate, and an energy generating element is provided. The liquid is supplied from the liquid supply port to the flow path, is supplied with energy by the energy generating element, is discharged from the liquid ejection port, and lands on a recording medium such as paper.

An insulating layer or a protective layer covering the energy generating element or in many cases, an inorganic material layer for other various purposes is provided on the substrate. On the other hand, it is known that the flow path formation member and other structures on the substrate are formed of organic material layers. Particularly, when the organic material layer is formed of a photosensitive resin, high-precision formation can be performed by photolithography.

According to the method of manufacturing a liquid ejection head described in Japanese Patent Application Laid-open No. 2016-064641, for example, a dry film of a photosensitive resin layer serving as a liquid flow path is formed on a substrate having an inorganic material layer by a lamination method and the resulting object is exposed to light in the shape of the flow path. Next, a dry film of a photosensitive resin layer serving as a nozzle portion connecting an ejection port to the flow path and serving as the ejection port is laminated on the photosensitive resin layer serving as the flow path, the resulting object is exposed to light in the shape of the ejection port, and an uncured portion of each photosensitive resin layer is collectively removed by development, thereby forming the flow path, the nozzle portion, and the ejection port.

However, with a demand for inkjet image recording advancing further, performance required of ink has been also advancing, hence a solvent with a high boiling point may be added to the ink from the viewpoint of a fixing property with respect to a recorded matter. The thus obtained ink may penetrate between the photosensitive resin layer made of an epoxy resin or the like and other members such as a base material, may peel off the flow path formation member, or may deform the flow path formation member.

Accordingly, in a case where ink with high permeability is used, it is considered that with the configuration of Japanese Patent Application Laid-open No. 2016-064641, peeling-off or deformation of the flow path formation member progresses at a pace higher than that of the types of ink in the related art, hence there is room for improvement in terms of long-term reliability. For example, long-term utilization of an inkjet recording head may cause the flow path formation member to peel off from the substrate or may lead to a result in which desired ink ejection performance cannot be obtained.

Furthermore, adhesion between the photosensitive resin layer and the substrate depends on curability of the photosensitive resin. Japanese Patent Application Laid-open No. 2016-064641 discloses a substance obtained by containing PF₆⁻ or SbF₆⁻ in anion of a cationic photoinitiator (acid generator) of a photosensitive resin composition. The acid generator containing PF₆⁻ does not have sufficient acid strength to obtain high curability, and it is necessary to add thereto a large amount of acid generator containing PF₆⁻ to obtain high curability. However, in a case where a large amount of acid generator containing PF₆⁻ is added, physical properties of the cured article may be degraded because a large amount of an unreacted acid generator and a residue of the acid generator after the reaction are present in the cured article, and adhesion reliability between the photosensitive resin layer and other members such as the substrate may be degraded.

On the other hand, the acid generator containing SbF₆⁻ has been designated as a deleterious substance from the issue of toxicity, and utilization thereof is limited. Utilization of deleterious substances may threaten human health and global ecology and may also inhibit the implementation of a sustainable society, such as a decarbonized/recycling-oriented society. Hydrogen fluoride may be generated and there may be a concern about wire corrosion depending on a utilization method, and the process of utilization and the amount of addition are thus limited.

On the other hand, from the viewpoint of improving efficiency of manufacturing of the liquid ejection head, the photosensitive resin forming the flow path formation member on the substrate and the photosensitive resin forming the ejection port formation member may be exposed using light with the same wavelength and may be collectively developed. As a result of studies, the present inventors have recognized that in a case where an acid generator in the relate art such as an acid generator containing PF₆⁻ is used in the method, deformation of the ejection port formation member or peeling-off of the flow path formation member may occur.

### SUMMARY

The present disclosure is directed to a method of manufacturing a liquid ejection head capable of curbing deformation of an ejection port formation member, further preventing ink from penetrating between a flow path formation member and other members, curbing peeling-off of the flow path formation member, and securing high reliability, and to the liquid ejection head.

The present disclosure relates to a method of manufacturing a liquid ejection head including, on a substrate, an ejection port formation member that forms an ejection port for discharging a liquid and a flow path formation member that forms a flow path that communicates with the ejection port,

the method including:
1) forming a layer of a photosensitive resin composition (1) forming the flow path formation member on the substrate;
2) pattern-exposing and heat-treating the layer of the photosensitive resin composition (1);
3) laminating a layer of a photosensitive resin composition (2) forming the ejection port formation member on the layer of the photosensitive resin composition (1);
4) pattern-exposing and heat-treating the layer of the photosensitive resin composition (2); and
5) removing unexposed portions of the layer of the photosensitive resin composition (1) and the layer of the photosensitive resin composition (2) to form the flow path formation member and the ejection port formation member, wherein
the photosensitive resin composition (1) contains
at least one epoxy resin selected from the group consisting of an epoxy resin having an aromatic ring and an alicyclic epoxy resin, and
a gallate-based photoacid generator having a salt structure represented by Formula (1) below and having a molar extinction coefficient of at least 0.10 L/mol·cm at a wavelength of 365 nm.

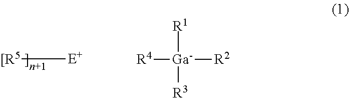

[In Formula (1), R¹ to R⁴ are each independently an alkyl group having 1 to 18 carbon atoms or Ar, and at least one of R¹ to R⁴ is Ar. The Ar is an aryl group having 6 to 14 carbon atoms (the number of carbon atoms of following substituents is not included), and some of hydrogen atoms in the aryl group may be substituted by an alkyl group having 1 to 18 carbon atoms, an alkyl group having 1 to 8 carbon atoms with a halogen atom substituted, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or an aryloxy group represented as —OR⁶, an acyl group represented as R⁷CO—, an acyloxy group represented as R⁸COO—, an alkylthio group or an arylthio group represented as —SR⁹, an amino group represented as —NR¹⁰R¹¹, or a halogen atom. The R⁶ to R⁹ are each independently an alkyl group having 1 to 8 carbon atoms or an aryl group having 6 to 14 carbon atoms, and R¹⁰ and R¹¹ are each independently a hydrogen atom, an alkyl group having 1 to 8 carbon atoms, or an aryl group having 6 to 14 carbon atoms. E represents an element with a valence n from Group 15 to Group 17 (IUPAC nomenclature), n being an integer of 1 to 3, R⁵ is an organic group bonded to E; the number of R⁵ is n+1, (n+1) R⁵ are allowed to be the same or differ from each other, and at least 2 R⁵ are allowed to form a cyclic structure including the element E directly thereamong or via O—, —S—, —SO—, —SO₂—, —NH—, —CO—, —COO—, —CONH—, an alkylene group, or a phenylene group.].

Also, the present disclosure relates to a liquid ejection head including, on a substrate:
an ejection port formation member that forms an ejection port for ejecting a liquid; and
a flow path formation member that forms a flow path that communicates with the ejection port, wherein
the flow path formation member is a cured article of a photosensitive resin composition (1),
the ejection port formation member is a cured article of a photosensitive resin composition (2), and
the photosensitive resin composition (1) contains
at least one epoxy resin selected from the group consisting of an epoxy resin having an aromatic ring and an alicyclic epoxy resin, and
a gallate-based photoacid generator having a salt structure represented by the Formula (1) and having a molar extinction coefficient of at least 0.10 L/mol·cm at a wavelength of 365 nm.

Features of the present disclosure will become apparent from the following description of embodiments with reference to the attached drawings. The following description of embodiments is described by way of examples.

### BRIEF DESCRIPTION OF THE DRAWINGS

FIG. 1A is a schematic perspective view illustrating a configuration of a liquid ejection head, and FIG. 1B is a schematic sectional view along the line A-A′ in FIG. 1A.

FIGS. 2A and 2B are schematic sectional views illustrating an example of a method of manufacturing a transfer member made of a photosensitive resin composition.

FIGS. 3A to 3H are schematic sectional views illustrating an example of a method of manufacturing the liquid ejection head.

FIGS. 4A to 4H are schematic sectional views illustrating an example of a method of manufacturing a liquid ejection head in an embodiment.

### DESCRIPTION OF THE EMBODIMENTS

In the present disclosure, the description of “from XX to YY” and “XX to YY” representing a numerical range means a numerical range including the lower limit and the upper limit which are endpoints, unless specified otherwise. When the numerical ranges are described in stages, the upper limits and lower limits of respective numerical ranges can be combined arbitrarily. Also, in the present disclosure, for example, the description such as “at least one selected from the group consisting of XX, YY and ZZ” means any of XX, YY, ZZ, a combination of XX and YY, a combination of XX and ZZ, a combination of YY and ZZ, or a combination of XX, YY and ZZ. When XX is a group, a plurality of constituents may be selected from XX, and the same applies to YY and ZZ.

Hereinafter, preferred embodiments of the present disclosure will be described with reference to the drawings. A method of manufacturing a liquid ejection head of the present disclosure is not limited to the following aspects. In addition, in the following description, components having the same function will be denoted by the same reference signs in the drawings, and the description thereof may be omitted.

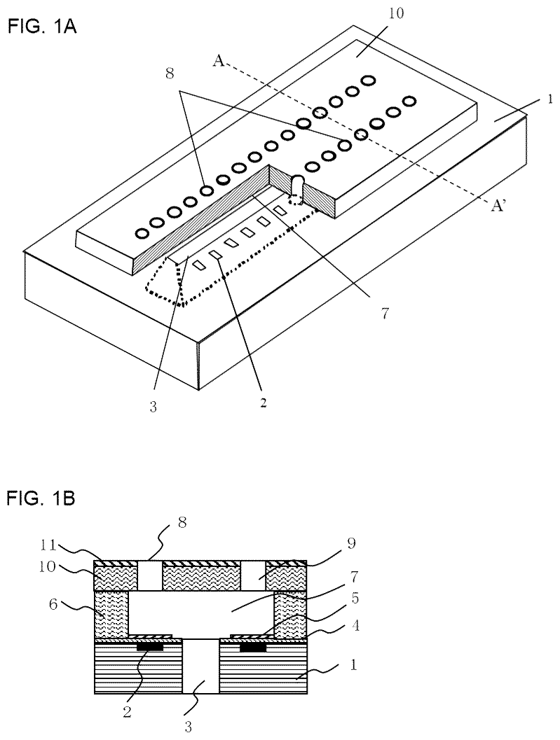

FIG. 1A is a schematic perspective view illustrating a liquid ejection head. FIG. 1B is a schematic sectional view of the liquid ejection head when seen in a plane perpendicular to a substrate passing through A-A′ in FIG. 1A.

The liquid ejection head illustrated in FIGS. 1A and 1B includes, on a substrate 1, an ejection port formation member 10 forming an ejection port 8 for ejecting a liquid and a flow path formation member 6 forming a flow path 7 communicating with the ejection port 8. The liquid ejection head has the substrate 1 on which energy generating elements 2 for generating energy for ejecting the liquid are formed at a predetermined pitch. The substrate 1 is formed of, for example, silicon. Examples of the energy generating elements 2 include electro-thermal conversion elements and piezoelectric elements. The energy generating elements 2 may be provided such that the energy generating elements 2 are in contact with the surface of the substrate 1, or may be provided partially in a hollow shape with respect to the surface of the substrate 1. A control signal input electrode (not illustrated) for operating the energy generating elements 2 is connected to the energy generating elements 2. Also, a supply port 3 for supplying an ink is opened in the substrate 1.

An inorganic material layer 4 and a protective layer 5 are formed in this order on the surface side of the substrate 1, specifically on the surface on the side of the ejection port 8. Examples of the substrate 1 include a silicon substrate formed of silicon. It is preferable that the silicon substrate be a single crystal of silicon, and a crystal orientation on the surface be (100).

It is preferable to have an inorganic material layer between the substrate and the flow path formation member. The flow path formation member is preferably in contact with the inorganic material layer. The inorganic material layer 4 preferably contains at least one selected from the group consisting of a metal film such as Ta, Ir, W, Ti, Pt, Au, Pd, Cu, Al, or Si, silicon oxide (SiO₂), silicon nitride (SiN), silicon carbide (SiC), silicon carbonitride (SiCN), and silicon oxycarbide (SiOC).

In FIG. 1B, the inorganic material layer 4 is used as a heat storage layer or an insulating layer. The protective layer 5 is adapted to protect the energy generating elements and is formed of, for example, Ta or Ir. The inorganic material layer 4 may cover the energy generating elements.

In FIG. 1B, the inorganic material layer 4 is formed over substantially the entire surface of the substrate 1. A sidewall of the flow path 7 is formed on the inorganic material layer 4 by the flow path formation member 6. Furthermore, the ejection port formation member 10 including the ejection port 8 and a nozzle portion 9 is formed on the flow path formation member 6 and the flow path 7. Also, a liquid-repellent layer 11 is formed on the ejection port formation member 10 as needed.

The liquid ejection head ejects the ink supplied from the supply port 3 through the flow path 7 as ink droplets from the ejection port 8 via the nozzle portion 9 by applying a pressure generated by the energy generating elements 2.

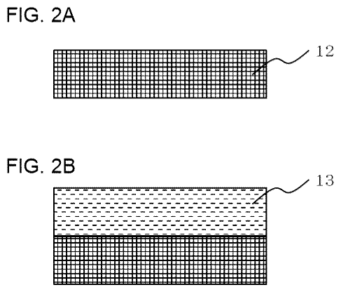

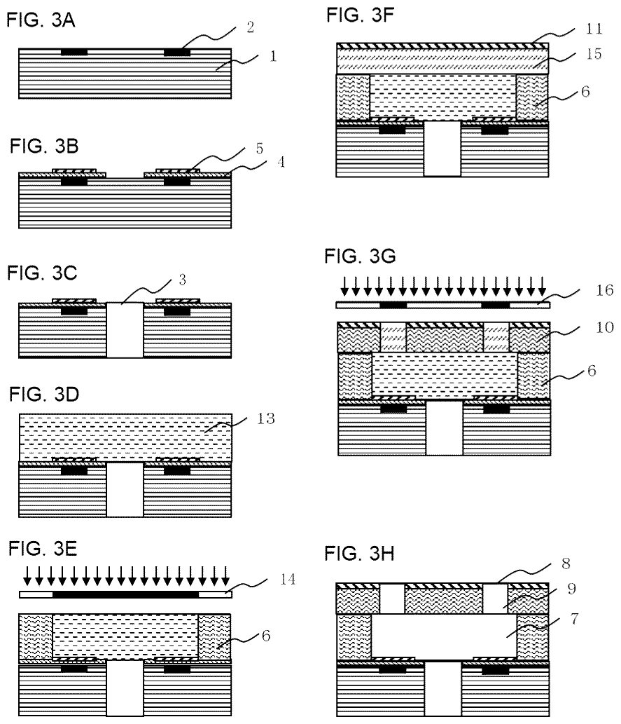

Next, a method of manufacturing the liquid ejection head will be described below with reference to FIGS. 2A, 2B, and 3A to 3H. FIGS. 2A and 2B are diagrams for explaining an example of a method of manufacturing a transfer member made of a photosensitive resin composition (1).

FIGS. 3A to 3H are schematic sectional views illustrating an example of a method of manufacturing the liquid ejection head, and are views when seen at the position of the same section as that of FIG. 1B in a completed state.

First, as illustrated in FIG. 2A, a film base material 12 made of PET, polyimide, or the like is prepared. Next, as illustrated in FIG. 2B, the photosensitive resin composition (1) 13 is applied to the film base material 12 by spin coating or slit coating and is pre-baked to thereby produce a transfer member made of the photosensitive resin composition (1).

The photosensitive resin composition (1) 13 can be a negative photosensitive epoxy resin composition in a case where it is transferred to a substrate with a liquid supply port formed thereon in advance. The photosensitive resin composition (1) contains, for example, an epoxy resin having a weight average molecular weight of equal to or greater than 5000, a polyhydric alcohol having two or three hydroxyl groups at the terminal and not containing a perfluoroalkyl group and a perfluoroalkylene group, a photoacid generator, and a solvent. The composition thereof will be described in detail later.

Since the thickness of the layer of the photosensitive resin composition (1) 13 corresponds to the height of the flow path, the thickness is appropriately determined depending on design of ejection of the liquid ejection head, is preferably set to 3 μm to 45 μm, is more preferably set to 3 μm to 30 μm, and is further preferably set to 5 μm to 20 μm, for example.

Next, as illustrated in FIG. 3A, the substrate 1 having the energy generating elements 2 on the front surface side is prepared.

Then, as illustrated in FIG. 3B, the inorganic material layer 4 is formed on the front surface side of the substrate 1 to cover the energy generating elements 2 as needed. Also, the protective layer 5 is formed on the inorganic material layer 4 on the outer surface side of the energy generating elements 2 as needed. The inorganic material layer 4 and the protective layer 5 may be patterned as needed.

Next, as illustrated in FIG. 3C, the supply port 3 penetrating through the substrate and supplying an ink is formed. The supply port 3 can be formed at a desired position using wet etching with an alkaline etching solution such as tetramethylammonium hydroxide (TMAH) or dry etching such as reactive ion etching.

Next, as illustrated in FIG. 3D, a film of the photosensitive resin composition (1) is formed on the substrate having the liquid ejection energy generating elements. For example, it is possible to produce the film by transferring a transfer member composed of the photosensitive resin composition (1) 13 produced in FIG. 2B to the substrate. In a case where the inorganic material layer 4 is provided, it is only necessary to transfer the transfer member to the inorganic material layer 4 on the substrate 1 where the energy generating elements 2 and the supply port 3 are disposed by using a laminating method. Note that in a case of a substrate with no supply port 3 disposed therein, the photosensitive resin composition (1) may not be used as the transfer member and may be applied by a spin coating method, a slit coating method, or the like, and the film may be formed.

The photosensitive resin composition (1) 13 is preferably formed of a cationic polymerization-type epoxy resin composition in consideration of adhesiveness to the ejection port formation member 10, which will be described later, mechanical strength, stability against a liquid such as an ink, resolution, and the like.

Next, as illustrated in FIG. 3E, the photosensitive resin composition (1) 13 is pattern-exposed via a flow path formation mask 14 having a flow path pattern, and further, the exposed part is cured through heat treatment (post exposure bake), thereby forming the flow path formation member 6. The mask 14 is formed by forming a light shielding film such as a chromium film on a substrate made of a material such as glass or quartz that transmits light having an exposure wavelength in accordance with the pattern of the flow path and the like. As an exposure device, it is possible to use a single-wavelength light source such as an i-line exposure stepper or a KrF stepper or a projection exposure device having a broad wavelength of a mercury lamp in a light source, such as a mask aligner MPA-600 Super (product name; manufactured by Canon Inc.).

Next, as illustrated in FIG. 3F, a photosensitive resin composition (2) 15 is applied to a film base material made of PET, polyimide, or the like, and is then transferred to the photosensitive resin composition (1) 13 and the flow path formation member 6 by a lamination method, thereby forming a film. Furthermore, a film of the liquid-repellent layer 11 is formed on the photosensitive resin composition (2) 15 as needed.

The photosensitive resin composition (2) 15 serving as the ejection port formation member 10 is preferably formed of a cationic polymerization-type epoxy resin composition in consideration of adhesiveness to the flow path formation member 6, mechanical strength, stability against a liquid such as an ink, resolution, and the like. Also, although the thickness of the photosensitive resin composition (2) 15 is appropriately determined depending on design of ejection of the liquid ejection head and is not particularly limited, the thickness is preferably set to 3 μm to 25 μm and is more preferably set to 3 μm to 15 μm, for example, from the viewpoint of mechanical strength and the like.

The liquid-repellent layer 11 is required to be liquid-repellent against a liquid such as an ink, and it is preferable to use a perfluoroalkyl composition or a perfluoropolyether composition having cationic polymerization properties. Generally, it is known that in the perfluoroalkyl composition and the perfluoropolyether composition, an alkyl fluoride chains are segregated at the interfaces between the compositions and the air by post-coating baking treatment, and it is possible to enhance the liquid-repellent properties on the surfaces of the compositions.

Next, as illustrated in FIG. 3G, the photosensitive resin composition (2) 15 and the liquid-repellent layer 11 are pattern-exposed via an ejection port formation mask 16 having an ejection port pattern. Furthermore, heat treatment (post exposure bake) is performed to cure the exposed part, thereby forming the ejection port formation member 10.

The present disclosure relates to a method of manufacturing a liquid ejection head including, on a substrate, a flow path formation member and an ejection port formation member. The manufacturing method includes:
1) a process of forming a layer of the photosensitive resin composition (1) to form the flow path formation member on the substrate;
2) a process of pattern-exposing and thermally treating the layer of the photosensitive resin composition (1);
3) a process of laminating a layer of the photosensitive resin composition (2) to form the ejection port formation member on the layer of the photosensitive resin composition (1);
4) a process of pattern-exposing and thermally treating the layer of the photosensitive resin composition (2); and
5) removing unexposed portions of the layer of the photosensitive resin composition (1) and the layer of the photosensitive resin composition (2) to form the flow path formation member and the ejection port formation member.

Also, the present disclosure provides a liquid ejection head including, on the substrate, the ejection port formation member that forms the ejection port for ejecting a liquid and a flow path formation member that forms the flow path communicating with the ejection port. In the liquid ejection head, the flow path formation member is a cured article of the photosensitive resin composition (1), and the ejection port formation member is a cured article of the photosensitive resin composition (2).

As described above, the photosensitive resin composition (1) that forms the flow path formation member on the substrate and the photosensitive resin composition (2) that forms the ejection port formation member may be exposed using light with the same wavelength. In a case where an acid generator in the related art is used in the method, deformation of the ejection port formation member or peeling-off of the flow path formation member may occur.

As a result of studies, the present inventors have recognized that the acid generator in the related art has insufficient anti-reflective ability, and deformation of the ejection port formation member may thus occur. In other words, the present inventors have recognized that there is a new problem that the photosensitive resin composition (2) is deformed due to reflected light if the anti-reflective ability of the photosensitive resin composition (1) is low in a case where the photosensitive resin composition (1) is exposed and the photosensitive resin composition (2) is then exposed. If the photosensitive resin composition (2) is deformed, deformation of the ejection port occurs.

Also, as a method for enhancing the anti-reflective ability using an acid generator in the related art in the photosensitive resin composition (1), there is a way to increase the amounts of acid generator and anti-reflective agent, for example. However, the inventors have recognized that if such a way is used, there is a problem that adhesiveness between the flow path formation member and other members such as the substrate and the inorganic material layer decreases and the flow path formation member peels off.

As a result of intensive studies, the present inventors have recognized that it is possible to solve the problem by using a gallate-based photoacid generator having a salt structure represented by Formula (1), which will be described later, and having a molar extinction coefficient of equal to or greater than 0.10 L/mol·cm at a wavelength of 365 nm in the photosensitive resin composition (1).

The inventors have considered the reason that the problem can be solved by the gallate-based photo acid generator as follows.

The gallate-based photoacid generator having a salt structure represented by Formula (1) and having a molar extinction coefficient of equal to or greater than 0.10 L/mol·cm at a wavelength of 365 nm has a satisfactory anti-reflective ability. Therefore, it is possible to reduce deformation of the photosensitive resin composition (2) due to reflected light at the time of exposure of the photosensitive resin composition (2) by using the gallate-based photoacid generator in the photosensitive resin composition (1).

The gallate-based photoacid generator has high anti-reflection ability. Thus, the anti-reflective ability of the photosensitive resin composition (1) can be enhanced without requiring large amounts of addition of an acid generator and an anti-reflective agent. As a result, it is believed that degradation of physical properties of the cured article of the photosensitive resin composition (1) is not caused by residues of the acid generator and the anti-reflective agent, adhesiveness of the flow path formation member is improved, and peeling-off can be reduced.

When the photosensitive resin composition (2) 15 is exposed using light having the same wavelength as that for the photosensitive resin composition (1) 13, the amount of exposure necessary to cure the photosensitive resin composition (2) 15 is preferably smaller than the amount of exposure necessary to cure the photosensitive resin composition (1) 13. Thus, when the photosensitive resin composition (2) 15 is exposed, light having been transmitted through the photosensitive resin composition (2) 15 is unlikely to cure the photosensitive resin composition (1) 13. As a result, the unexposed portion of the photosensitive resin composition (1) 13 is easily removed in a developing process, which will be described later, and the flow path 7 is easily formed. Therefore, it is preferable that the photosensitive resin composition (2) 15 have relatively higher sensitivity than the photosensitive resin composition (1) 13.

The amount of exposure necessary to cure the photosensitive resin composition (2) 15 is preferably equal to or less than 1/10 the amount of exposure necessary to cure the photosensitive resin composition (1) 13.

For example, the amount of exposure necessary to cure the photosensitive resin composition (2) 15 is 1/40 to 1/10 or 1/35 to 1/10 the amount of exposure necessary to cure the photosensitive resin composition (1) 13.

The amount of exposure necessary to cure the photosensitive resin composition (1) 13 is preferably, for example, 5000 J/m² to 25000 J/m² or 10000 J/m² to 20000 J/m².

The amount of exposure necessary to cure the photosensitive resin composition (2) 15 is preferably, for example, 150 J/m² to 2500 J/m² or 300 J/m² to 1000 J/m².

The amounts of exposure necessary to cure the photosensitive resin compositions can be controlled by the amounts of a photoacid generator and the amount of addition of a basic substance such as amines or an acid generator that generates weakly acidic (pKa=−1.5 to 3.0) toluenesulfonic acid and the like.

The ejection port formation mask 16 is obtained by forming a light shielding film such as a chromium film on a substrate made of a material such as glass or quartz that transmits light having an exposure wavelength in accordance with the pattern of the ejection port. As an exposure device, it is possible to use a single-wavelength light source such as an i-line exposure stepper or a KrF stepper or a projection exposure device having a broad wavelength of a mercury lamp in a light source, such as a mask aligner MPA-600 Super (product name; manufactured by Canon Inc.).

Next, as illustrated in FIG. 3H, the photosensitive resin composition (1) 13, the photosensitive resin composition (2) 15, and the uncured portion of the liquid-repellent layer 11 are developed with a developing agent and are thereby collectively removed to form the flow path 7, the ejection port 8, and the nozzle portion 9, and heat treatment is performed thereon as needed to complete the liquid ejection head. Examples of the developing agent include propylene glycol monomethyl ether acetate (PGMEA), methyl isobutyl ketone (MIBK), xylene, and the like. Furthermore, rinsing with isopropyl alcohol (IPA) may be performed as needed.

In the above manufacturing method, after the photosensitive resin composition (1) 13 is exposed, the photosensitive resin composition (2) 15 is laminated on the flow path formation member 6 and the photosensitive resin composition (1) 13. However, it is also possible to laminate the photosensitive resin composition (2) 15 prior to the exposure of the photosensitive resin composition (1) 13.

Although in the above-described method of manufacturing the liquid ejection head, the flow path formation member 6 and the ejection port formation member 10 are formed in two layers, the present disclosure is not limited to the aspect. More photosensitive resins may be used to form each member.

The photosensitive resin compositions will be described below.

The photosensitive resin composition (1) and the photosensitive resin composition (2) are preferably formed of a cationic polymerization-type epoxy resin compositions in consideration of adhesive performance of the cured articles thereof, mechanical strengths, liquid (ink) resistance, swelling resistance, reactivity as photolithography materials, resolutions, and the like.

The photosensitive resin composition (1) contains an epoxy resin. Specifically, the photosensitive resin composition (1) contains at least one epoxy resin selected from the group consisting of an epoxy resin having an aromatic ring and an alicyclic epoxy resin. The photosensitive resin composition (2) may also contain an epoxy resin. The description “photosensitive resin composition” below relates to both the photosensitive resin composition (1) and the photosensitive resin composition (2). The epoxy resin preferably has at least one skeleton selected from the group consisting of a bisphenol skeleton, a phenol novolac skeleton, a cresol novolac skeleton, a norbornene skeleton, a cyclic terpene skeleton, and a dicyclopentadiene skeleton.

Examples of the epoxy resin having an aromatic ring include at least one selected from the group consisting of a bisphenol A epoxy resin, a bisphenol F epoxy resin, a phenol novolac epoxy resin, and a cresol novolac epoxy resin. Also, examples of the alicyclic epoxy resin include at least one selected from the group consisting of alicyclic epoxy resins having at least one skeleton selected from the group consisting of a norbornene skeleton, a cyclic terpene skeleton, and a dicyclopentadiene skeleton.

The photosensitive resin composition preferably contains at least one selected from the group consisting of a bisphenol A epoxy resin, a bisphenol F epoxy resin, and a cresol novolac epoxy resin.

The photosensitive resin composition may contain other epoxy resins than the epoxy resin having an aromatic ring.

The content percentage of the epoxy resin having an aromatic ring in the epoxy resin contained in the photosensitive resin composition is preferably 50% by mass to 100% by mass and is more preferably 60% by mass to 100% by mass.

The photosensitive resin composition is preferably a cationic photopolymerization epoxy resin composition. The epoxy resin contained in the photosensitive resin composition preferably contains a bifunctional or higher functional epoxy resin having two or more epoxy groups per molecule. The epoxy resin may contain, for example, a bifunctional epoxy resin and a trifunctional or higher functional epoxy resin, or may contain a bifunctional epoxy resin and a trifunctional epoxy resin. Utilization of bifunctional or higher functional epoxy resins leads to three-dimensional crosslinking of the cured articles and is thus suitable for obtaining desired properties. The content percentage of the bifunctional or higher functional (bifunctional, for example) epoxy resin in the epoxy resin is preferably 50% by mass to 100% by mass and is more preferably 80% by mass to 100% by mass. The photosensitive resin composition preferably contains 10% by mass to 45% by mass or more preferably contains 20% by mass to 45% by mass of trifunctional or higher functional (trifunctional, for example) epoxy resin with reference to the mass of the epoxy resin.

In the case of a liquid ejection head obtained by performing transferring while applying heat to a substrate having an opening and a recessed portion, the photosensitive resin composition (1) 13 preferably has heat resistance against a heat process among the processes in consideration of stability of the pattern shape. For example, the photosensitive resin composition (1) 13 preferably has film strength such that the layer is not deformed even in an uncured state in a case where the photosensitive resin composition (1) 13 is transferred as a dry film while heat is applied to the substrate having an opening and a recessed portion or in another heat process such as heat treatment after exposure.

Therefore, the epoxy resin contained in the photosensitive resin composition (1) 13 preferably has a high weight average molecular weight. Specifically, the weight average molecular weight (Mw) of the epoxy resin contained in the photosensitive resin composition (1) 13 is preferably 5,000 to 100,000. The softening point of the epoxy resin contained in the photosensitive resin composition (1) 13 is preferably equal to or greater than 90° C.

If the weight average molecular weight (Mw) is equal to or greater than 5,000, the film strength is improved, moldability of the photosensitive resin composition (1) 13 is improved during transferring or in other heat processes, and the height of the layer becomes uniform. In addition, if the softening point is equal to or greater than 90° C., the film strength is likely to be improved in a similar manner. On the other hand, if the weight average molecular weight (Mw) is equal to or less than 100,000, crosslinking density of the photosensitive resin composition is likely to be improved, and stability of the pattern shape becomes satisfactory.

Furthermore, the epoxy resin in the photosensitive resin composition (1) 13 is preferably a bifunctional or higher functional epoxy resin and preferably contains a bifunctional epoxy resin and a trifunctional or higher functional epoxy resin from the viewpoint of reactivity. By containing the trifunctional or higher functional epoxy resin, crosslinking progresses in a three-dimensional manner, and it is possible to improve sensitivity as a photosensitive material.

The trifunctional or higher functional epoxy resin preferably has an epoxy equivalent of less than 500. If the epoxy equivalent is less than 500, satisfactory sensitivity is achieved, pattern resolution is improved, and satisfactory mechanical strength and adhesion of the cured article are achieved. The weight average molecular weight (Mw) of these resins can be calculated in terms of polystyrene using gel permeation chromatography (manufactured by Shimadzu Corporation, for example).

The photosensitive resin composition (2) preferably contains a polyfunctional epoxy resin. The photosensitive resin composition (2) preferably contains a novolac epoxy resin.

Commercially available epoxy resins that can be used as the photosensitive resin composition (1) 13 serving the flow path formation member and the photosensitive resin composition (2) 15 serving as the ejection port formation member include the following epoxy resins: “Celloxide 2021”, “GT-300 series, and “GT-400 series” (product names) manufactured by Daicel Chemical Industries, Ltd., “jER1004”, “jER1007”, “jER1009”, “jER1009F”, “jER1009SK”, “jER1010”, “jER1256”, and “157S70” (product names) manufactured by Mitsubishi Chemical Corporation, “EPICLON N-695”, ‘EPICLON N-865”, “EPICLON 4050”, “EPICLON 7050”, “EPICLON HP-6000”, “EPICLON HP-4710”, “EPICLON HP-7200 series”, “EPICLON EXA-4816” (product names), and “EPOX MKR-1710” (product names) manufactured by DIC Corporation, “Denacol series” (product name) manufactured by Nagase ChemteX Corporation, and “EP-4000 series” (product name) manufactured by ADEKA Corporation.

The photosensitive resin composition (1) contains a gallate-based photoacid generator having a salt structure represented by Formula (1) below and having a molar extinction coefficient of equal to or greater than 0.10 L/mol·cm at a wavelength of 365 nm. The photosensitive resin composition (2) may also contain the gallate-based photoacid generator having a salt structure represented by Formula (1) below and having a molar extinction coefficient of equal to or greater than 0.10 L/mol·cm at a wavelength of 365 nm.

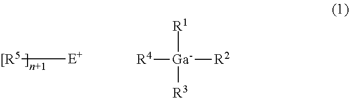

In Formula (1), R¹ to R⁴ are each independently an alkyl group having 1 to 18 carbon atoms or Ar, and at least one of R¹ to R⁴ is Ar.

Ar is an aryl group having 6 to 14 carbon atoms (the number of carbon atoms of the following substituents is not included), and some of hydrogen atoms in the aryl group may be substituted by an alkyl group having 1 to 18 carbon atoms, an alkyl group having 1 to 8 carbon atoms with a halogen atom substituted, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or an aryloxy group represented as —OR⁶, an acyl group represented as R⁷CO—, an acyloxy group represented as R⁸COO—, an alkylthio group or an arylthio group represented as —SR⁹, an amino group represented as —NR¹⁰R¹¹, or a halogen atom. R⁶ to R⁹ are each independently an alkyl group having 1 to 8 carbon atoms or an aryl group having 6 to 14 carbon atoms, and R¹⁰ and R¹¹ are each independently a hydrogen atom, an alkyl group having 1 to 8 carbon atoms, or an aryl group having 6 to 14 carbon atoms.

It is preferred that all of R¹ to R⁴ are Ar. Ar is an aryl group having 6 to 14 carbon atoms (preferably 6 to 10 carbon atoms or more preferably 6 carbon atoms; the number of carbon atoms in the following substituents is not included), and some of hydrogen atoms in the aryl group is substituted by an alkyl group having 1 to 8 carbon atoms (preferably 1 to 3 carbon atoms or more preferably one carbon atom) with a halogen atom substituted, or a halogen atom. It is preferable that 50% to 100% of the hydrogen atoms in the aryl group is substituted by a halogen atom. The halogen atom is preferably F.

E represents an element with a valence n from Group 15 to Group 17 (IUPAC nomenclature). E is preferably S. n is an integer of 1 to 3 and is preferably 2. R⁵ is an organic group bonded to E, the number of R⁵ is n+1, and (n+1) R⁵ may be the same or differ from each other. 2 or more R⁵ may form a cyclic structure including the element E directly among them or via O—, —S—, —SO—, —SO₂—, —NH—, —CO—, —COO—, —CONH—, an alkylene group, or a phenylene group.

It is preferable that (n+1) R⁵ are each independently an alkyl group having 1 to 8 carbon atoms (preferably 1 to 3 carbon atoms), an aryl group (some of hydrogen atoms in the aryl group may be substituted by a hydroxy group or a halogen atom) having 6 to 14 carbon atoms (preferably 6 to 10 carbon atoms), or a group having an aromatic ring and a sulfur element. Examples of the group having an aromatic ring and a sulfur element include at least one selected from the group consisting of a group having a sulfonio structure, a group having a diphenyl sulfone structure, and a group having a thioxanthone structure.

As a cationic moiety represented as [R⁵]ₙ₊₁+-E⁺ in Formula (1), it is possible to select an onium-based cationic moiety with high absorbance and to select an onium ion such as oxonium, ammonium, phosphonium, sulfonium, or iodonium, and among these, a sulfonium-based cationic moiety that is excellent in cationic polymerization performance and crosslinking reaction performance is further preferable. In other words, the cationic moiety represented as [R⁵]ₙ₊₁-E⁺ in Formula (1) is preferably a sulfonium-based cationic moiety.

Examples of the cationic moiety represented as [R⁵]ₙ₊₁E⁺ in Formula (1) include at least one selected from the group consisting of triaryl sulfonium such as triphenyl sulfonium, tri-p-tolyl sulfonium, tri-o-tolyl sulfonium, tris(4-methoxyphenyl)sulfonium, 1-naphthyl diphenyl sulfonium, 2-naphthyl diphenyl sulfonium, tris(4-fluorophenyl)sulfonium, tri-1-naphthyl sulfonium, tri-2-naphthyl sulfonium, tris(4-hydroxyphenyl)sulfonium, 4-(phenylthio)phenyldiphenyl sulfonium, 4-(p-tolylthio)phenyldi-p-tolyl sulfonium, 4-(4-methoxyphenylthio)phenylbis(4-methoxyphenyl)sulfonium, 4-(phenylthio)phenylbis(4-fluorophenyl)sulfonium, 4-(phenylthio)phenylbis(4-methoxyphenyl)sulfonium, 4-(phenylthio)phenyldi-p-tolyl sulfonium, [4-(4-biphenylylthio)phenyl]-4-biphenylylphenyl sulfonium, [4-(2-thioxanetonylthio)phenyl]diphenyl sulfonium, bis[4-(diphenylsulfonio)phenyl]sulfide, bis[4-{bis[4-(2-hydroxyethoxy)phenyl]sulfonio}phenyl]sulfide, bis{4-[bis(4-fluorophenyl)sulfonio]phenyl}sulfide, bis{4-[bis(4-methylphenyl)sulfonio]phenyl}sulfide, bis{4-[bis(4-methoxyphenyl)sulfonio]phenyl}sulfide, 4-(4-benzoyl-2-chlorophenylthio)phenylbis(4-fluorophenyl)sulfonium, 4-(4-benzoyl-2-chlorophenylthio)phenyl diphenyl sulfonium, 4-(4-benzoylphenylthio)phenylbis(4-fluorophenyl)sulfonium, 4-(4-benzoylphenylthio)phenyldiphenyl sulfonium, 7-isopropyl-9-oxo-10-thia-9,10-dihydroanthracene-2-yldi-p-tolyl sulfonium, 7-isopropyl-9-oxo-10-thia-9,10-dihydroanthracene-2-yldiphenyl sulfonium, 2-[(di-p-tolyl)sulfonio]thioxanthone, 2-[(diphenyl)sulfonio]thioxanthone, 4-(9-oxo-9H-thioxanthen-2-yl)thiophenyl-9-oxo-9H-thioxanthen-2-ylphenyl sulfonium, 4-[4-(4-tert-butylbenzoyl)phenylthio]phenyldi-p-tolyl sulfonium, 4-[4-(4-tert-butylbenzoyl)phenylthio]phenyldiphenyl sulfonium, 4-[4-(benzoylphenylthio)]phenyldi-p-tolyl sulfonium, 4-[4-(benzoylphenylthio)]phenyldiphenyl sulfonium, 5-(4-methoxyphenyl)thiaanthrenium, 5-phenylthiaanthrenium, 5-tolylthiaanthrenium, 5-(4-ethoxyphenyl)thiaanthrenium, and 5-(2,4,6-trimethylphenyl)thiaanthrenium; diaryl sulfonium such as diphenylphenacyl sulfonium, diphenyl 4-nitrophenacyl sulfonium, diphenylbenzyl sulfonium, and diphenylmethylsulfonium; monoaryl sulfonium such as phenylmethylbenzylsulfonium, hydroxyphenylmethyl sulfonium, 4-methoxyphenylmethylbenzyl sulfonium, 4-acetocarbonyloxyphenylmethylbenzyl sulfonium, 4-hydroxyphenyl-methyl-1-naphthyl methyl sulfonium, 4-hydroxyphenyl (2-naphthyl methyl)methyl sulfonium, 2-naphthyl methylbenzyl sulfonium, 2-naphthyl methyl (1-ethoxycarbonyl)ethyl sulfonium, phenylmethylphenacyl sulfonium, 4-hydroxyphenylmethylphenacyl sulfonium, 4-methoxyphenylmethylphenacyl sulfonium, 4-acetocarbonyloxyphenylmethylphenacyl sulfonium, 2-naphthylmethylphenacyl sulfonium, 2-naphthyloctadecylphenacyl sulfonium, and 9-anthracenylmethylphenacyl sulfonium; and trialkyl sulfonium such as dimethylphenacylsulfonium, phenacyltetrahydrothiophenium, dimethylbenzylsulfonium, benzyltetrahydrothiophenium, and octadecylmethylphenacylsulfonium.

The cationic moiety represented as [R⁵]ₙ₊₁-E⁺ in Formula (1) is preferably at least one selected from the group consisting of 4-hydroxyphenyl-methyl-1-naphthyl methyl sulfonium, [4-(4-biphenylthio)phenyl]-4-biphenylylphenyl sulfonium, 2-[(di-p-tolyl)sulfonio]thioxanthone, and 2-[(diphenyl)sulfonio]thioxanthone.

From the viewpoint of cationic photopolymerization and anti-reflection, the molar extinction coefficient of the gallate-based photoacid generator having the salt structure represented by Formula (1) at a wavelength of 365 nm is equal to or greater than 0.10 L/mol·cm. The molar extinction coefficient of the gallate-based photoacid generator is preferably 0.10 L/mol·cm to 7.00 L/mol·cm and is more preferably 0.30 L/mol·cm to 5.00 L/mol·cm. The molar extinction coefficient of the gallate-based photoacid generator can be controlled, for example, by the structure of the cationic moiety.

The content of the gallate-based photoacid generator having the salt structure represented by Formula (1) is preferably 0.5 parts by mass to 10.0 parts by mass and is more preferably 1.0 parts by mass to 5.0 parts by mass with respect to 100 parts by mass of epoxy resin. If the content is equal to or greater than 0.5 parts by mass, satisfactory curability is achieved. Also, if the content is equal to or less than 10.0 parts by mass, the amount of unreacted residue decreases, and more satisfactory adhesiveness is achieved.

The photosensitive resin composition (1) may contain other photoacid generators than the gallate-based photoacid generator having the salt structure represented by Formula (1) and having a molar extinction coefficient of equal to or greater than 0.10 L/mol·cm at a wavelength of 365 nm within a range that does not impair the effect of the present disclosure. The content of other photoacid generators in the photosensitive resin composition (1) is preferably 0 parts by mass to 3.0 parts by mass and is more preferably 0 parts by mass to 1.0 parts by mass with respect to 100 parts by mass of epoxy resin. Within the above range, the amount of unreacted residue decreases, and more satisfactory adhesiveness is achieved.

The photosensitive resin composition (1) may contain an additive having an anti-reflective function. The additive having an anti-reflective function is preferably a compound having a molar extinction coefficient of equal to or greater than 0.1 L/mol·cm at a wavelength of 365 nm. Examples of the molar extinction coefficient of the additive with an anti-reflective function include 0.1 L/mol·cm to 40.0 L/mol·cm and 3.0 L/mol·cm to 30.0 L/mol·cm.

A method of measuring the molar extinction coefficients of the photoacid generator and the additive is as follows.

Each target compound is dissolved in a solvent with no absorption at 365 nm, such as acetonitrile, for example, to obtain a solution, the solution is input to a cell made of quartz, and light absorbance at 365 nm is measured using a UV-visible-NIR Spectrophotometer (manufactured by JASCO Corporation). The molar extinction coefficient can be calculated from the absorbance obtained by the following equation.

Molar absorbance coefficient=Absorbance/Molar concentration of Compound/Optical path of cell

The light absorbance of the layer of the photosensitive resin composition (1) per 1 μm of film thickness at a wavelength of 365 nm is preferably equal to or greater than 0.01 abs/μm. Preferable examples of the light absorbance include 0.01 abs/μm to 0.05 abs/μm or 0.01 abs/μm to 0.04 abs/μm.

The light absorbance of the layer of the photosensitive resin composition (2) per 1 μm of film thickness at a wavelength of 365 nm is preferably equal to or greater than 0.01 abs/μm. Preferable examples of the light absorbance include 0.01 abs/μm to 0.05 abs/μm or 0.01 abs/μm to 0.04 abs/μm.

If the light absorbance per 1 μm of film thickness is equal to or greater than 0.01 abs/μm, satisfactory stability of the pattern shape is achieved. Also, a large amount of addition is not needed to obtain desired light absorbance for anti-reflection, by using the compound having a molar extinction coefficient of equal to or greater than 0.1 L/mol·cm. As a result, the amount of uncured residue decreases, and more satisfactory adhesiveness is achieved.

A method of measuring the light absorbance of the layer of the photosensitive resin composition per 1 μm of film thickness at a wavelength of 365 nm is as follows.

A film of the target photosensitive resin composition is formed on a quartz substrate, and the light absorbance at 365 nm is measured using a UV-visible-NIR Spectrophotometer (manufactured by JASCO Corporation). By dividing the obtained value of light absorbance by the film thickness after the film formation, the light absorbance per 1 μm of film thickness at 365 nm can be calculated.

Furthermore, the additive having an anti-reflective function preferably provides a sensitizing effect on the cationic photopolymerization initiator upon i-line irradiation. Polycyclic aromatic or heterocyclic rings, dyes, metal complexes, and the like generate energy transfer upon i-line irradiation, and can assist reactivity of the cationic photopolymerization initiator with weak i-line absorption. Specific examples of the additive having an anti-reflective function include a compound having an anthracene structure, a compound having a carbazole structure, and curcumin. In particular, a compound having an anthracene structure is preferable because there is no concern of yellow discoloration and even a small amount of addition can provide its effect.

In particular, dialkoxyanthracene is highly soluble in resins and is more preferable. On the other hand, a compound that generates radicals by causing hydrogen extraction or electron transfer through i-line irradiation is also effective in assisting the cationic photopolymerization initiator. Specific examples thereof include a compound having an anthraquinone structure and a compound having a thioxanthone structure. The additive having an anti-reflective function is preferably at least one selected from the group consisting of a compound having an anthracene structure, a compound having an anthraquinone structure, and a compound having a thioxanthone structure.

Examples of the compound having an anthracene structure include compounds in which hydrogen atoms in anthracene are substituted by an alkyl group having 1 to 6 carbon atoms (preferably 1 to 4 carbon atoms) or an alkoxy group having 1 to 6 carbon atoms (preferably 1 to 4 carbon atoms). The compound having an anthracene structure is preferably, for example, diethoxyanthracene or dibutoxyanthracene.

Examples of the compound having an anthraquinone structure include compounds in which hydrogen atoms in anthraquinone are substituted by an alkyl group having 1 to 6 carbon atoms (preferably 1 to 4 carbon atoms) or an alkoxy group having 1 to 6 carbon atoms (preferably 1 to 4 carbon atoms). The compound having an anthraquinone structure is preferably, for example, ethylanthraquinone.

Examples of the compound having a thioxanthone structure include compounds in which hydrogen atoms in thioxanthone are substituted by an alkyl group having 1 to 6 carbon atoms (preferably 1 to 4 carbon atoms) or an alkoxy group having 1 to 6 carbon atoms (preferably 1 to 4 carbon atoms). The compounds having a thioxanthone structure is preferably, for example, diethylthioxanthone.

When these additives are used, a high effect can be obtained when these are combined with a cationic polymerization initiator containing an iodonium salt having high electron affinity from among onium salts. It is possible to use one kind or a combination of two or more kinds from these.

Examples of commercially available additives include “Curcumin”, “2-Ethylanthraquinone”, and “2-Isopropylthioxanthone” (product names) manufactured by Fujifilm Wako Pure Chemical Corporation, “Anthracure UVS-1331” and “Anthracure UVS-1101” (product names) manufactured by Air Water Performance Chemical Inc., “Omnicat250” and “OmnipolTX” (product names) manufactured by IGM Resins, and “CPI-410S” and “CPI-410B” (product names) manufactured by San-Apro Ltd.

The content of the additive may be appropriately determined in accordance with the amount of exposure of the photosensitive resin composition (2), the film thickness of the photosensitive resin composition (1), and reflectance of a film that is present on the substrate surface and is not particularly limited. From the viewpoint of adhesiveness, the content of the additive having an anti-reflective function is preferably 0.05 parts by mass to 5.0 parts by mass, is more preferably 0.1 parts by mass to 1.3 parts by mass, and is further preferably 0.1 parts by mass to 0.4 parts by mass with respect to 100 parts by mass of epoxy resin. If the content is equal to or less than the upper limit, satisfactory curability is achieved, and more satisfactory adhesiveness is achieved. Also, a satisfactory patterning property of the cured article is also achieved.

Furthermore, the content ratio between the gallate-based photoacid generator contained in the photosensitive resin composition (1) and the additive having an anti-reflective function is preferably within the following range from the viewpoint of curability. In other words, the content of the gallate-based photoacid generator contained in the photosensitive resin composition (1) is preferably equal to or greater than three times, is more preferably 3 times to 15 times, and is further preferably 3 times to 10 times as high as the content of the additive having an anti-reflective function.

Furthermore, a silane coupling agent can also be added for the purpose of improving adhesion performance. In other words, the photosensitive resin composition (1) preferably contains a silane coupling agent. Examples of commercially available silane coupling agents include “A-187” (product name) manufactured by Momentive Performance Materials Inc. For the purpose of improving adhesion performance, a polyhydric alcohol such as polyethylene glycol can also be added as a polymerization reaction promoter.

The content of the silane coupling agent in the photosensitive resin composition (1) is preferably 1 part by mass to 10 parts by mass and is more preferably 2 parts by mass to 5 parts by mass with respect to 100 parts by mass of epoxy resin.

In addition, a photosensitizer such as an anthracene compound, a basic substance such as amines, an acid generator for generating weakly acidic (pKa=−1.5 to 3.0) toluenesulfonic acid, and the like can also be added to improve pattern resolution and adjust sensitivity (the amount of exposure necessary for curing). In other words, the photosensitive resin composition (1) and the photosensitive resin composition (2) preferably contain either a basic substance or a weakly acidic (pKa=−1.5 to 3.0) acid generator. The photosensitive resin composition (1) and the photosensitive resin composition (2) preferably contain an acid generator that generates a weakly acidic (pKa =−1.5 to 3.0) toluenesulfonic acid. The weakly acidic (pKa=−1.5 to 3.0) acid generator can correspond to other acid generators described above.

Examples of commercially available acid generators for generating a toluenesulfonic acid include “TPS-1000” (product name) manufactured by Midori Kagaku Co., Ltd. and “WPAG-367” (product name) manufactured by Wako Pure Chemical Corporation. Examples of the content of acid generator of pKa=−1.5 to 3.0 in the photosensitive resin composition (1) and the photosensitive resin composition (2) include 0.002 part by mass to 1.0 parts by mass, 0.003 parts by mass to 0.50 parts by mas, and 0.003 parts by mass to 0.05 parts by mass with respect to 100 parts by mass of epoxy resin.

It is also possible to use “SU-8 series” and “KMPR-1000” (product names) manufactured by Kayaku MicroChem Corporation, and “TMMR S2000” and “TMMF S2000” (product names) manufactured by Tokyo Ohka Kogyo Co., Ltd, which are commercially available as negative resists.

The photosensitive resin composition (1) preferably contains a polyhydric alcohol. The polyhydric alcohol is preferably a polyhydric alcohol that does not contain a perfluoroalkyl group and a perfluoroalkylene group.

Examples of the polyhydric alcohol include at least one selected from the group consisting of: polyethylene glycol such as PEG200, PEG600, and PEG1000; trimethylolalkane such as trimethylolethane and trimethylpropane; an aliphatic alcohol having 1 to 10 carbon atoms (preferably 2 to 8 carbon atoms) such as 1,6-hexandiol; and polyether polyol. The polyhydric alcohol preferably has two or three hydroxyl groups at a terminal and preferably has a repeated structure in a molecule. For example, the polyhydric alcohol is preferably at least one selected from the group consisting of polyethylene glycol and polyether polyol.

The content of polyhydric alcohol in the photosensitive resin composition (1) is preferably 0.5 parts by mass to 30.0 part by mass, is more preferably 1.0 parts by mass to 10.0 parts by mass, and is further preferably 1.5 parts by mass to 5.0 parts by mass with respect to 100 parts by mass of epoxy resin.

The photosensitive resin composition may contain a known solvent such as propylene glycol monomethyl ether acetate (PGMEA) as needed. The amount of solvent may be appropriately changed in accordance with a way of forming the film of the photosensitive resin composition, for example.

### EXAMPLES

Although the present disclosure will be described in further detail by showing examples below, the present disclosure is not limited to these examples.

### Examples 1 to 30

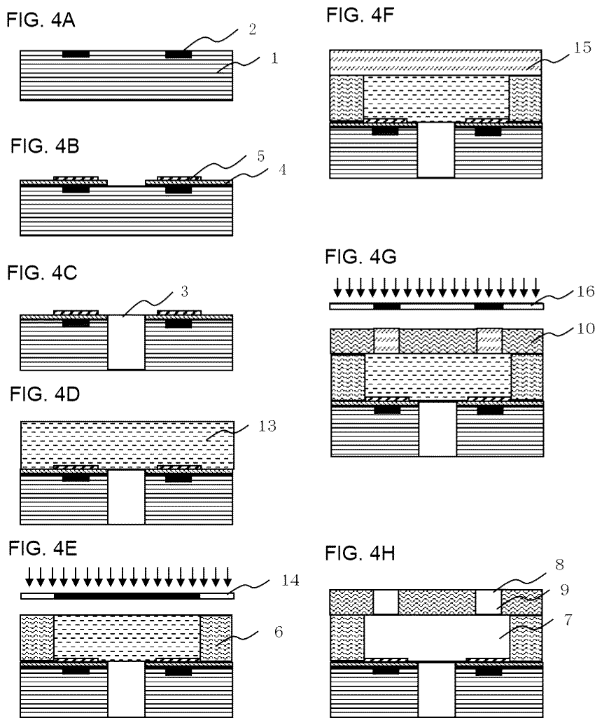

For each example, a liquid ejection head was made by the processes illustrated in FIGS. 2A and 2B and FIGS. 4A to 4H using the photosensitive resin composition (1) and the photosensitive resin composition (2) described in Tables 1 to 4. In each table, the composition is expressed in units of parts by mass. Note that sensitivity of each photosensitive resin compositions (1) was adjusted using a-5/c-6 material such that the amount of exposure necessary to cure the photosensitive resin composition (2) was smaller than the amount of exposure necessary to cure the photosensitive resin composition (1).

TABLE 1

| | | Molar extinction | Photosensitive resin composition (2) | | | | | | | |
|---|---|---|---|---|---|---|---|---|---|---|
| Component | | coefficient at 365 nm | 1 | 2 | 3 | 4 | 5 | 6 | 7 | 8 |
| Epoxy | e-1 | — | 100 | 100 | 100 | 100 | 100 | 100 | 100 | 100 |
| resin | | | | | | | | | | |
| Photoacid | a-1/c-1 | 0.46 | 10 | — | — | — | — | — | — | — |
| generator | a-1/c-2 | 0.56 | — | 10 | — | — | — | — | — | — |
| | a-2/c-1 | 0.51 | — | — | 8 | — | — | — | — | — |
| | a-2/c-2 | 0.62 | — | — | — | 8 | — | — | — | — |
| | a-1/c-3 | 4.58 | — | — | — | — | 3 | — | — | — |
| | a-1/c-4 | 4.78 | — | — | — | — | — | 3 | — | — |
| | a-3/c-5 | 6.48 | — | — | — | — | — | — | 3 | — |
| | a-4/c-5 | 4.13 | — | — | — | — | — | — | — | 3 |
| | a-5/c-6 | 0.01 | 0.03 | 0.03 | 0.03 | 0.03 | 0.03 | 0.03 | 0.03 | 0.03 |
| Solvent | PGMEA | — | 180 | 180 | 180 | 180 | 180 | 180 | 180 | 180 |

| | | | | | | | | |
|---|---|---|---|---|---|---|---|---|
| Film thickness [μm] | 6 | 6 | 6 | 6 | 6 | 6 | 6 | 6 |
| Light absorbance | 0.028 | 0.035 | 0.025 | 0.03 | 0.035 | 0.035 | 0.04 | 0.03 |
| per film thickness [abs/μm] | | | | | | | | |

TABLE 2

| | | | Molar | | | | | |
|---|---|---|---|---|---|---|---|---|
| | | | extinction | Photosensitive resin composition (1) | | | | |
| Component | | | coefficient | 1 | 2 | 3 | 4 | 5 |
| Trifunctional or | | e-2 | — | 100 | 100 | 100 | 100 | 100 |
| higher functional | | | | | | | | |
| epoxy resin (a) | | e-3 | — | — | — | — | — | — |
| Bifunctional | | e-4 | — | 200 | 200 | 200 | 200 | 200 |
| epoxy resin (b) | | e-5 | — | — | — | — | — | — |
| Photoacid | Gallate salt | a-1/c-1 | 0.46 | 8 | — | — | — | — |
| generator | | a-1/c-2 | 0.56 | — | 8 | — | — | — |
| | | a-2/c-1 | 0.51 | — | — | 10 | — | — |
| | | a-2/c-2 | 0.62 | — | — | — | 10 | — |
| | | a-1/c-3 | 4.58 | — | — | — | — | 6 |
| | | a-1/c-4 | 4.78 | — | — | — | — | — |
| | SO3-salt | a-5/c-6 | 0.01 | 0.3 | 0.3 | 0.4 | 0.4 | 0.2 |
| | PF6-salt | a-3/c-5 | 6.48 | — | — | — | — | — |
| | BF6-salt | a-4/c-5 | 4.13 | — | — | — | — | — |
| | SbF6-salt | a-6/c-7 | 0.22 | — | — | — | — | — |
| Anti-reflective | Anthracene | b-1 | 28.2 | 1 | 1 | 1 | 1 | 0.5 |
| additive | derivative | | | | | | | |
| | Anthracene | b-2 | 17.4 | — | — | — | — | — |
| | derivative | | | | | | | |
| | Anthraquinone | b-3 | 3.98 | — | — | — | — | — |
| | derivative | | | | | | | |
| | Thioxanthone | b-4 | 12.3 | — | — | — | — | — |
| | derivative | | | | | | | |
| | Anthracene | b-5 | 0.04 | — | — | — | — | — |
| | derivative | | | | | | | |
| Silane coupling agent | | A-187 | — | 11 | 11 | 11 | 11 | 11 |
| Adhesiveness | | PEG200 | — | — | — | — | — | — |
| improving additive | | PEG600 | — | 8 | 8 | 8 | 8 | 8 |
| | | PEG1000 | — | — | — | — | — | — |
| | | Trimethylolpropane | — | — | — | — | — | — |
| | | 1,6-hexanediol | — | — | — | — | — | — |
| | | Polyether | — | — | — | — | — | — |
| | | polyol: diol | | | | | | |
| | | Polyether | — | — | — | — | — | — |
| | | polyol: triol | | | | | | |
| Solvent | | PGMEA | — | 650 | 650 | 650 | 650 | 650 |
| Film thickness/μm | | | | 10 | 10 | 10 | 10 | 10 |
| Light absorbance per film thickness [abs/μm] | | | | 0.02 | 0.02 | 0.025 | 0.025 | 0.03 |
| | | | Molar | | | | | |
| | | | extinction | Photosensitive resin composition (1) | | | | |
| Component | | | coefficient | 6 | 7 | 8 | 9 | 10 |
| Trifunctional or | | e-2 | — | 100 | 100 | 100 | 100 | 100 |
| higher functional | | | | | | | | |
| epoxy resin (a) | | e-3 | — | — | — | — | — | — |
| Bifunctional | | e-4 | — | 200 | 200 | 200 | 200 | 200 |
| epoxy resin (b) | | e-5 | — | — | — | — | — | — |
| Photoacid | Gallate salt | a-1/c-1 | 0.46 | — | — | — | — | — |
| generator | | a-1/c-2 | 0.56 | — | — | 8 | 8 | 8 |
| | | a-2/c-1 | 0.51 | — | — | — | — | — |
| | | a-2/c-2 | 0.62 | — | — | — | — | — |
| | | a-1/c-3 | 4.58 | — | 6 | — | — | — |
| | | a-1/c-4 | 4.78 | 6 | — | — | — | — |
| | SO3-salt | a-5/c-6 | 0.01 | 0.2 | 0.2 | 0.5 | 0.5 | 0.3 |
| | PF6-salt | a-3/c-5 | 6.48 | — | — | 2 | — | — |
| | BF6-salt | a-4/c-5 | 4.13 | — | — | — | 2 | — |
| | SbF6-salt | a-6/c-7 | 0.22 | — | — | — | — | — |
| Anti-reflective | Anthracene | b-1 | 28.2 | 0.5 | — | — | — | — |
| additive | derivative | | | | | | | |
| | Anthracene | b-2 | 17.4 | — | 0.7 | — | — | 1 |
| | derivative | | | | | | | |
| | Anthraquinone | b-3 | 3.98 | — | — | — | — | — |
| | derivative | | | | | | | |
| | Thioxanthone | b-4 | 12.3 | — | — | — | — | — |
| | derivative | | | | | | | |
| | Anthracene | b-5 | 0.04 | — | — | — | — | — |
| | derivative | | | | | | | |

| Silane coupling agent | A-187 | — | 11 | 11 | 11 | 11 | 11 |
|---|---|---|---|---|---|---|---|
| Adhesiveness | PEG200 | — | — | — | — | — | — |
| improving additive | PEG600 | — | 8 | 8 | 8 | 8 | 8 |
| | PEG1000 | — | — | — | — | — | — |
| | Trimethylolpropane | — | — | — | — | — | — |
| | 1,6-hexanediol | — | — | — | — | — | — |
| | Polyether | — | — | — | — | — | — |
| | polyol: diol | | | | | | |
| | Polyether | — | — | — | — | — | — |
| | polyol: triol | | | | | | |
| Solvent | PGMEA | — | 650 | 650 | 650 | 650 | 650 |

| | | | | | |
|---|---|---|---|---|---|
| Film thickness/μm | 10 | 10 | 10 | 10 | 10 |
| Light absorbance per film thickness [abs/μm] | 0.03 | 0.028 | 0.01 | 0.01 | 0.015 |

TABLE 3

| | | | Molar | | | | | |
|---|---|---|---|---|---|---|---|---|
| | | | extinction | Photosensitive resin composition (1) | | | | |
| Component | | | coefficient | 11 | 12 | 13 | 14 | 15 |
| Trifunctional or | | e-2 | — | 100 | 100 | 100 | 100 | 100 |
| higher functional | | | | | | | | |
| epoxy resin (a) | | e-3 | — | — | — | — | — | — |
| Bifunctional | | e-4 | — | 200 | 200 | 200 | 200 | 200 |
| epoxy resin (b) | | e-5 | — | — | — | — | — | — |
| Photoacid | Gallate salt | a-1/c-1 | — | — | — | — | — | — |
| generator | | a-1/c-2 | 0.56 | 8 | 8 | — | — | 8 |
| | | a-2/c-1 | 0.51 | — | — | — | — | — |
| | | a-2/c-2 | 0.62 | — | — | — | — | — |
| | | a-1/c-3 | 4.58 | — | — | 7 | — | — |
| | | a-1/c-4 | 4.78 | — | — | — | 7 | — |
| | SO3-salt | a-5/c-6 | 0.01 | 0.3 | 0.3 | 0.25 | 0.25 | 0.3 |
| | PF6-salt | a-3/c-5 | 6.48 | — | — | — | — | — |
| | BF6-salt | a-4/c-5 | 4.13 | — | — | — | — | — |
| | SbF6-salt | a-6/c-7 | 0.22 | — | — | — | — | — |
| Anti-reflective | Anthracene | b-1 | 28.2 | — | — | — | — | 1 |
| additive | derivative | | | | | | | |
| | Anthracene | b-2 | 17.4 | — | — | — | — | — |
| | derivative | | | | | | | |
| | Anthraquinone | b-3 | 3.98 | 3 | — | — | — | — |
| | derivative | | | | | | | |
| | Thioxanthone | b-4 | 12.3 | — | 1.5 | — | — | — |
| | derivative | | | | | | | |
| | Anthracene | b-5 | 0.04 | — | — | — | — | — |
| | derivative | | | | | | | |
| Silane coupling agent | | A-187 | — | 11 | 11 | 11 | 11 | 11 |
| Adhesiveness | | PEG200 | — | — | — | — | — | 6 |
| improving additive | | PEG600 | — | 8 | 8 | 8 | 8 | — |
| | | PEG1000 | — | — | — | — | — | — |
| | | Trimethylolpropane | — | — | — | — | — | — |
| | | 1,6-hexanediol | — | — | — | — | — | — |
| | | Polyether | — | — | — | — | — | — |
| | | polyol: diol | | | | | | |
| | | Polyether | — | — | — | — | — | — |
| | | polyol: triol | | | | | | |
| Solvent | | PGMEA | — | 650 | 650 | 650 | 650 | 650 |
| Film thickness/μm | | | | 10 | 10 | 10 | 10 | 10 |
| Light absorbance per film thickness [abs/μm] | | | | 0.01 | 0.015 | 0.03 | 0.03 | 0.02 |
| | | | Molar | | | | | |
| | | | extinction | Photosensitive resin composition (1) | | | | |
| Component | | | coefficient | 16 | 17 | 18 | 19 | 20 |
| Trifunctional or | | e-2 | — | 100 | 100 | 100 | 100 | 100 |
| higher functional | | | | | | | | |
| epoxy resin (a) | | e-3 | — | — | — | — | — | — |
| Bifunctional | | e-4 | — | 200 | 200 | 200 | 200 | 200 |
| epoxy resin (b) | | e-5 | — | — | — | — | — | — |
| Photoacid | Gallate salt | a-1/c-1 | — | — | — | — | — | — |
| generator | | a-1/c-2 | 0.56 | 8 | 8 | 8 | 8 | 8 |
| | | a-2/c-1 | 0.51 | — | — | — | — | — |
| | | a-2/c-2 | 0.62 | — | — | — | — | — |
| | | a-1/c-3 | 4.58 | — | — | — | — | — |
| | | a-1/c-4 | 4.78 | — | — | — | — | — |
| | SO3-salt | a-5/c-6 | 0.01 | 0.3 | 0.3 | 0.3 | 0.3 | 0.3 |
| | PF6-salt | a-3/c-5 | 6.48 | — | — | — | — | — |
| | BF6-salt | a-4/c-5 | 4.13 | — | — | — | — | — |
| | SbF6-salt | a-6/c-7 | 0.22 | — | — | — | — | — |
| Anti-reflective | Anthracene | b-1 | 28.2 | 1 | 1 | 1 | 1 | 1 |
| additive | derivative | | | | | | | |
| | Anthracene | b-2 | 17.4 | — | — | — | — | — |
| | derivative | | | | | | | |
| | Anthraquinone | b-3 | 3.98 | — | — | — | — | — |
| | derivative | | | | | | | |
| | Thioxanthone | b-4 | 12.3 | — | — | — | — | — |
| | derivative | | | | | | | |
| | Anthracene | b-5 | 0.04 | — | — | — | — | — |
| | derivative | | | | | | | |

| Silane coupling agent | A-187 | — | 11 | 11 | 11 | 11 | 11 |
|---|---|---|---|---|---|---|---|
| Adhesiveness | PEG200 | — | — | — | — | — | — |
| improving additive | PEG600 | — | — | — | — | — | — |
| | PEG1000 | — | 5 | — | — | — | — |
| | Trimethylolpropane | — | — | 5 | — | — | — |
| | 1,6-hexanediol | — | — | — | 5 | — | — |
| | Polyether | — | — | — | — | 5 | — |
| | polyol: diol | | | | | | |
| | Polyether | — | — | — | — | — | 3 |
| | polyol: triol | | | | | | |
| Solvent | PGMEA | — | 650 | 650 | 650 | 650 | 650 |

| | | | | | |
|---|---|---|---|---|---|
| Film thickness/μm | 10 | 10 | 10 | 10 | 10 |
| Light absorbance per film thickness [abs/μm] | 0.02 | 0.02 | 0.02 | 0.02 | 0.02 |

TABLE 4

| | | | Molar | | | | | | |
|---|---|---|---|---|---|---|---|---|---|
| | | | extinction | Photosensitive resin composition (1) | | | | | |
| Component | | | coefficient | 21 | 22 | 23 | 24 | 25 | 26 |
| Trifunctional | | e-2 | — | — | 100 | 100 | 100 | 100 | 100 |
| or higher functional | | | | | | | | | |
| epoxy resin (a) | | e-3 | — | 100 | — | — | — | — | — |
| Bifunctional | | e-4 | — | 200 | — | 150 | 200 | 200 | 200 |
| epoxy resin (b) | | e-5 | — | — | 150 | — | — | — | — |
| Photoacid | Gallate salt | a-1/c-1 | 0.46 | — | — | — | — | — | — |
| generator | | a-1/c-2 | 0.56 | 8 | 8 | 8 | — | — | — |
| | | a-2/c-1 | 0.51 | — | — | — | — | — | — |
| | | a-2/c-2 | 0.62 | — | — | — | — | — | — |
| | | a-1/c-3 | 4.58 | — | — | — | — | — | — |
| | | a-1/c-4 | 4.78 | — | — | — | — | — | — |
| | SO3-salt | a-5/c-6 | 0.01 | 0.3 | 0.4 | 0.4 | 0.1 | 0.1 | 0.1 |
| | PF6-salt | a-3/c-5 | 6.48 | — | — | — | — | — | — |
| | BF6-salt | a-4/c-5 | 4.13 | — | — | — | — | — | — |
| | SbF6-salt | a-6/c-7 | 0.22 | — | — | — | 12 | 25 | 10 |
| Anti-reflective | Anthracene | b-1 | 28.2 | 1 | 1 | 1 | — | — | — |
| additive | derivative | | | | | | | | |
| | Anthracene | b-2 | 17.4 | — | — | — | — | — | — |
| | derivative | | | | | | | | |
| | Anthraquinone | b-3 | 3.98 | — | — | — | — | — | — |
| | derivative | | | | | | | | |
| | Thioxanthone | b-4 | 12.3 | — | — | — | — | — | — |
| | derivative | | | | | | | | |
| | Anthracene | b-5 | 0.04 | — | — | — | — | — | 30 |
| | derivative | | | | | | | | |

| Silane coupling | A-187 | — | 11 | 11 | 11 | 11 | 11 | 11 |
|---|---|---|---|---|---|---|---|---|
| Adhesiveness | PEG200 | — | — | — | — | — | — | — |
| improving additive | PEG600 | — | 8 | 8 | 8 | 8 | 8 | 8 |
| | PEG1000 | — | — | — | — | — | — | — |
| | Trimethylolpropane | — | — | — | — | — | — | — |
| | 1,6-hexanediol | — | — | — | — | — | — | — |
| | Polyether | — | — | — | — | — | — | — |
| | polyol: diol | | | | | | | |
| | Polyether | — | — | — | — | — | — | — |
| | polyol: triol | | | | | | | |
| Solvent | PGMEA | — | 650 | 650 | 650 | 650 | 650 | 650 |

| | | | | | | |
|---|---|---|---|---|---|---|
| Film thickness/μm | 10 | 10 | 10 | 10 | 10 | 10 |
| Light absorbance per film thickness [abs/μm] | 0.02 | 0.02 | 0.02 | 0.004 | 0.01 | 0.01 |

In each table, the molar extinction coefficient indicates the molar extinction coefficient (L/mol·cm) at a wavelength of 365 nm. As the materials in each table, the following materials were used.
e-1: 157S70 (manufactured by Mitsubishi Chemical Corporation; product name)
e-2: EPICLON N-695 (manufactured by DIC Corporation; product name)
e-3: EPICLON HP-7200H (manufactured by DIC Corporation; product name)
e-4: jER1009F (manufactured by Mitsubishi Chemical Corporation; product name)
e-5: jER1009SK (manufactured by Mitsubishi Chemical Corporation; product name)
b-1: Anthracure UVS-1331 (manufactured by Air Water Performance Chemical Inc.; product name)
b-2: Anthracure UVS-1101 (manufactured by Air Water Performance Chemical Inc.; product name)
b-3: 2-Ethylanthraquinone (Fujifilm Wako Pure Chemical Corporation; product name)
b-4: OmniradDETX (IGM Resins; product name)
b-5: Anthracure UVS-2171 (manufactured by Air Water Performance Chemical Inc.; product name)

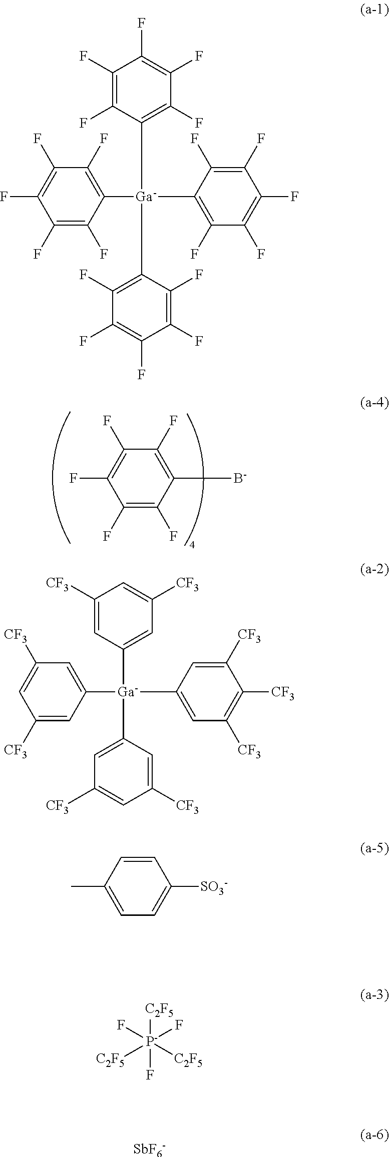

c-1: 4-hydroxyphenyl-methyl-1-naphthylmethyl sulfonium
c-2: [4-(4-biphenylylthio)phenyl]-4-biphenylylphenyl sulfonium
c-3:2-[(di-p-tolyl)sulfonio]thioxanthone
c-3:2-[(diphenyl)sulfonio]thioxanthone

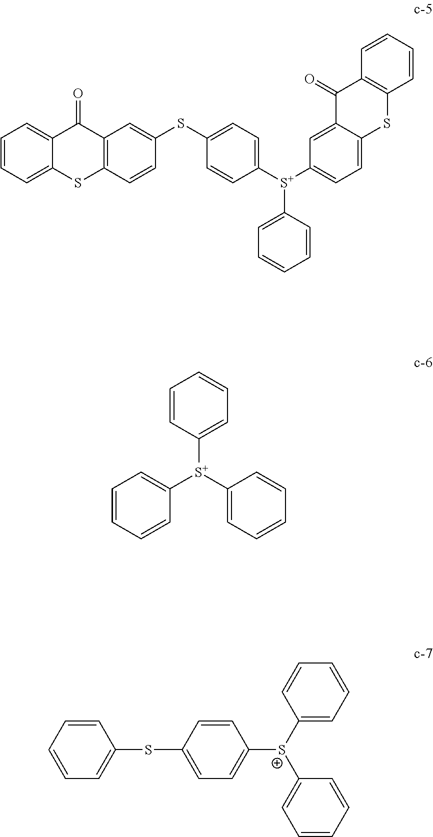 [SMILES: O=c1c2ccccc2sc2ccc(Sc3ccc([S+](c4ccccc4)c4ccc5sc6ccccc6c(=O)c5c4)cc3)cc12 ; c1ccc([S+](c2ccccc2)c2ccccc2)cc1 ; c1ccc(Sc2ccc([S+](c3ccccc3)c3ccccc3)cc2)cc1]

### Example 1

First, as illustrated in FIG. 2A, a PET film 12 with a thickness of 100 μm was prepared.

Next, as illustrated in FIG. 2B, the photosensitive resin composition (1) 1 of the composition described in Table 2 was applied onto the PET film 12 as the reference sign 13 in FIG. 2B by spin coating, and the resulting object was then baked at 90° C. for 10 minutes to volatilize the PGMVEA solvent, thereby forming a film of 7.0 μm.

Next, as illustrated in FIG. 4A, the substrate 1 formed of silicon and having energy generating elements 2 made of TaSiN on the front surface side was prepared.

Next, as illustrated in FIG. 4B, Ta was formed with a thickness of 100 nm as the inorganic material layer 4 and the protective layer 5 by the sputtering method on the front surface side of the substrate 1 such that the energy generating elements 2 are covered. Furthermore, the inorganic material layer 4 and the protective layer 5 were patterned by a photolithography process and reactive ion etching.

Then, the supply port 3 was formed as illustrated in FIG. 4C. The supply port 3 was formed by forming an etching mask with an opening using a positive-type photosensitive resin made of OFPR (manufactured by Tokyo Ohka Kogyo Co., Ltd.) and performing reactive ion etching through the opening of the etching mask. The reactive ion etching was performed by a Bosch process using an ICP etching device (manufactured by Alcatel-Lucent Enterprise; model number: 8E). After the supply port 3 was formed, the etching mask was removed using a release agent.

Next, as illustrated in FIG. 4D, the photosensitive resin composition (1) (reference sign 13 in FIG. 4D) was formed. Specifically, a film provided with the photosensitive resin composition (1) produced in FIG. 2B was transferred to the substrate 1 on which the energy generating elements 2 and the supply port 3 were disposed by applying heat of 70° C. using a laminating method and applying a pressure thereto. Thereafter, the PET film 12 was peeled off from the photosensitive resin composition (1) by a peeling tape (not illustrated).

Next, as illustrated in FIG. 4E, the photosensitive resin composition (1) was pattern-exposed with the amount of exposure of 16000 J/m² using an i-line exposure stepper (manufactured by Canon Inc.; product name: i5) via the flow path formation mask 14 having the flow path pattern, and the exposed portion was cured by further performing heat treatment at 50° C. for 5 minutes thereon, thereby forming the flow path formation member 6.

Next, as illustrated in FIG. 4F, the photosensitive resin composition (2) 8 in Table 1 was formed as the reference sign 15 in FIG. 4F. First, the photosensitive resin composition (2) 8 in Table 1 was applied onto a PET film with a thickness of 100 m, and the resulting object was baked at 90° C. for 5 minutes to volatilize the solvent, thereby forming a film of 5.0 m. Next, the photosensitive resin composition (2) was transferred to and laminated on the photosensitive resin composition (1) and the flow path formation member 6 with heat at 50° C. applied thereto by using a laminating method.

Next, as illustrated in FIG. 4G, the photosensitive resin composition (2) was pattern-exposed with the amount of exposure of 500 J/m² using an i-line exposure stepper (manufactured by Canon Inc.; product name: i5) via the ejection port formation mask 16 having the ejection port pattern. Furthermore, the exposed portion was cured by further performing heat treatment at 90° C. for 5 minutes, thereby forming the ejection port formation member 10.

Next, as illustrated in FIG. 4H, the uncured portions of the photosensitive resin composition (1) and the photosensitive resin composition (2) were collectively removed by developing them with PGMEA for 1 hour, and the flow path 7, the ejection port 8, and the nozzle portion 9 were formed and cured at heat of 200° C., thereby obtaining a liquid ejection head.

### Examples 2 to 30

Liquid ejection heads in Examples 2 to 30 were obtained similarly to Example 1 other than that changes to the photosensitive resin compositions (1) and the photosensitive resin compositions (2) described in Tables 1 to 4 were made in combinations in Table 7 in Example 1.

### Comparative Examples 1 to 3

Liquid ejection heads in Comparative Example 1 to 3 were obtained similarly to Example 1 other than that changes to the photosensitive resin compositions (1) and the photosensitive resin compositions (2) described in Tables 1 to 4 were made in combinations in Table 7 in Example 1.

### Evaluation

### Pattern Shape

In each of the liquid ejection heads produced in Examples 1 to 30 and Comparative Examples 1 to 3, the area of the ejection port pattern was measured by a white interference microscope (manufactured by Hitachi High-Tech Science Corporation), and the pattern shape (pattern reproducibility) was determined using criteria shown in Table 5 from a value of a ratio of the measured area of pattern to the mask area (230 μm²).

TABLE 5

| | Measured area/mask area(230 μm²) | | |
|---|---|---|---|
| | | Less than 0.9 | |
| | Equal to | and equal to | |
| | or greater | or greater | |
| | than 0.9 | than 0.8 | Less than 0.8 |
| Pattern reproducibility | A | B | C |

The evaluation results of the pattern shapes are shown in Table 7. In each of the liquid ejection heads produced in Examples 1 to 30, satisfactory pattern reproducibility was achieved. On the other hand, Comparative Example 1 did not contain a gallate-based photoacid generator having the salt structure represented by Formula (1) and having a molar extinction coefficient of equal to or greater than 0.10 L/mol·cm at a wavelength of 365 nm. Therefore, it was considered that the anti-reflective ability was insufficient, the ejection port was deformed due to reflected light at the time of exposure of the photosensitive resin composition (2), and the pattern reproducibility was degraded.

### Peeling Test (Ink Resistance)

The flow path of each of the liquid ejection heads produced in Examples 1 to 30 and Comparative Examples 1 to 3 was filled with an ink shown in Table 6 below and was left for 90 days in an oven at 80° C.

TABLE 6

| Blended component | Parts by mass |
|---|---|
| Diethylene glycol | 10.0 |
| 2-pyrrolidone | 5.0 |
| 1,2-hexanediol | 7.0 |
| Triethylene glycol monobutyl ether | 25.0 |
| Acetylenol | 1.0 |
| Black pigment | 3.0 |
| Pure water | 49.0 |

The joined state between the inorganic material layer 4 and the flow path formation member 6 after being left was observed with a metal microscope and was evaluated using the following criteria.

A: Even after storage at 80° C. for 90 days, no peeling occurred between the inorganic material layer 4 and the flow path formation member 6.

B: After storage at 80° C. for 90 days, slight peeling that had not been observed at the time of completion of the liquid ejection head and did not affect ejection occurred between the inorganic material layer 4 and the flow path formation member 6.

C: After storage at 80° C. for 90 days, peeling that had not been observed at the time of completion of the liquid ejection head occurred between the inorganic material layer 4 and the flow path formation member 6.

Evaluation results of the peeling test are shown in Table 7. In each of the liquid ejection heads produced in Examples 1 to 30, no peeling was observed between the inorganic material layer and the flow path formation member, or even in a case where peeling occurred, the peeling was slight peeling that did not affect ejection, and satisfactory ink resistance was achieved. Comparative Examples 2 and 3 did not contain the gallate-based photoacid generator having the salt structure represented by Formula (1) and having a molar extinction coefficient of equal to or greater than 0.10 L/mol·cm at a wavelength of 365 nm. It is considered that adhesiveness between the inorganic material layer and the flow path formation member was degraded due to resides and the like of the photoacid generator and the anti-reflective agent and peeling that had not been observed at the time of completion of the liquid ejection head was observed between the inorganic material layer and the flow path formation member.

TABLE 7

| | Examples | | | | | | | | | | | | | | | | | |
|---|---|---|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 | 16 | 17 | 18 |
| Photosensitive resin | 8 | 8 | 8 | 8 | 8 | 8 | 8 | 8 | 8 | 8 | 8 | 8 | 8 | 8 | 8 | 8 | 8 | 8 |
| composition (2) | | | | | | | | | | | | | | | | | | |
| Photosensitive resin | 1 | 2 | 3 | 4 | 5 | 6 | 7 | 8 | 9 | 10 | 11 | 12 | 13 | 14 | 15 | 16 | 17 | 18 |
| composition (1) | | | | | | | | | | | | | | | | | | |
| Pattern shape | A | A | A | A | A | A | A | B | B | B | B | B | A | A | A | A | A | A |
| Peeling test | A | A | B | B | A | A | A | A | A | A | A | A | A | A | A | B | A | A |

| | | | | | | | | | | | | | Comparative | | |
|---|---|---|---|---|---|---|---|---|---|---|---|---|---|---|---|
| | Examples | | | | | | | | | | | | Examples | | |
| | 19 | 20 | 21 | 22 | 23 | 24 | 25 | 26 | 27 | 28 | 29 | 30 | 1 | 2 | 3 |
| Photosensitive resin | 8 | 8 | 8 | 8 | 8 | 1 | 2 | 3 | 4 | 5 | 6 | 7 | 7 | 7 | 7 |
| composition (2) | | | | | | | | | | | | | | | |
| Photosensitive resin | 19 | 20 | 21 | 22 | 23 | 1 | 1 | 1 | 1 | 1 | 1 | 1 | 24 | 25 | 26 |
| composition (1) | | | | | | | | | | | | | | | |
| Pattern shape | A | A | A | A | A | A | A | A | A | A | A | A | C | B | B |
| Peeling test | A | B | A | A | A | A | A | A | A | A | A | A | B | C | C |

### Printing Evaluation

Each of the liquid ejection heads produced in the examples and the comparative examples was filled with an ink similar to that used in the peeling test, and printing evaluation after storage at 70° C. for 90 days was conducted.

In each of the liquid ejection heads produced in Examples 1 to 30, satisfactory printing evaluation was achieved. On the other hand, in Comparative Examples 1 to 3, pattern reproducibility was degraded, partial peeling occurred between the inorganic material layer and the flow path formation member, and degradation of printing quality was thus observed.

According to the present disclosure, it is possible to provide a liquid ejection head capable of reducing deformation of an ejection port formation member, further preventing ink from penetrating between a flow path formation member and other members, reducing peeling-off of the flow path formation member, and securing high reliability.

In addition, the technology described in the present specification can replace an acid generator containing SbF₆⁻. In other words, the technologies described in this specification have the potential to contribute to the achievement of a sustainable society, such as a decarbonized society/circular society.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-188172, filed Oct. 25, 2024, which is hereby incorporated by reference herein in its entirety.

What is claimed is:

1. A method of manufacturing a liquid ejection head comprising, on a substrate, an ejection port formation member that forms an ejection port for discharging a liquid and a flow path formation member that forms a flow path that communicates with the ejection port,
the method comprising:
1) forming a layer of a photosensitive resin composition (1) forming the flow path formation member on the substrate;
2) pattern-exposing and heat-treating the layer of the photosensitive resin composition (1);
3) laminating a layer of a photosensitive resin composition (2) forming the ejection port formation member on the layer of the photosensitive resin composition (1);
4) pattern-exposing and heat-treating the layer of the photosensitive resin composition (2); and
5) removing unexposed portions of the layer of the photosensitive resin composition (1) and the layer of the photosensitive resin composition (2) to form the flow path formation member and the ejection port formation member, wherein
the photosensitive resin composition (1) contains
at least one epoxy resin selected from the group consisting of an epoxy resin having an aromatic ring and an alicyclic epoxy resin, and
a gallate-based photoacid generator having a salt structure represented by Formula (1) below and having a molar extinction coefficient of at least 0.10 L/mol·cm at a wavelength of 365 nm: 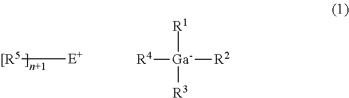
In Formula (1), R¹ to R⁴ are each independently an alkyl group having 1 to 18 carbon atoms or Ar, and at least one of R¹ to R⁴ is Ar; the Ar is an aryl group having 6 to 14 carbon atoms (the number of carbon atoms of following substituents is not included), and some of hydrogen atoms in the aryl group may be substituted by an alkyl group having 1 to 18 carbon atoms, an alkyl group having 1 to 8 carbon atoms with a halogen atom substituted, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or an aryloxy group represented as —OR⁶, an acyl group represented as R⁷CO—, an acyloxy group represented as R⁸COO—, an alkylthio group or an arylthio group represented as —SR⁹, an amino group represented as —NR¹⁰R¹¹, or a halogen atom; the R⁶ to R⁹ are each independently an alkyl group having 1 to 8 carbon atoms or an aryl group having 6 to 14 carbon atoms, and R¹⁰ and R¹¹ are each independently a hydrogen atom, an alkyl group having 1 to 8 carbon atoms, or an aryl group having 6 to 14 carbon atoms; E represents an element with a valence n from Group 15 to Group 17 (IUPAC nomenclature), n being an integer of 1 to 3, R⁵ is an organic group bonded to E; the number of R⁵ is n+1, (n+1) R⁵ are allowed to be the same or differ from each other, and at least 2 R⁵ are allowed to form a cyclic structure including the element E directly thereamong or via —O, —S—, —SO—, —SO₂—, —NH—, —CO—, —COO—, —CONH—, an alkylene group, or a phenylene group.

2. The method of manufacturing a liquid ejection head according to claim 1, wherein
a light absorbance of the layer of the photosensitive resin composition (1) per film thickness of 1 μm at the wavelength of 365 nm is at least 0.01 abs/μm, and
a light absorbance of the layer of the photosensitive resin composition (2) per film thickness of 1 μm at the wavelength of 365 nm is at least 0.01 abs/μm.

3. The method of manufacturing a liquid ejection head according to claim 1, wherein a cationic moiety represented as [R⁵]ₙ₊₁-E⁺ in Formula (1) above is a sulfonium-based cationic moiety.

4. The method of manufacturing a liquid ejection head according to claim 1, wherein an amount of exposure necessary to cure the photosensitive resin composition (2) is smaller than an amount of exposure necessary to cure the photosensitive resin composition (1).

5. The method of manufacturing a liquid ejection head according to claim 1, wherein a content of the gallate-based photoacid generator is 0.5 parts by mass to 10.0 parts by mass with respect to 100 parts by mass of the epoxy resin.

6. The method of manufacturing a liquid ejection head according to claim 1, wherein the epoxy resin has at least one skeleton selected from the group consisting of a bisphenol skeleton, a phenol novolac skeleton, a cresol novolac skeleton, a norbornene skeleton, a cyclic terpene skeleton, and a dicyclopentadiene skeleton.

7. The method of manufacturing a liquid ejection head according to claim 1, wherein the epoxy resin in the photosensitive resin composition (1) contains a bifunctional or higher functional epoxy resin.

8. The method of manufacturing a liquid ejection head according to claim 1, wherein the epoxy resin in the photosensitive resin composition (1) contains a bifunctional epoxy resin and a trifunctional or higher functional epoxy resin.

9. The method of manufacturing a liquid ejection head according to claim 1, wherein
the photosensitive resin composition (1) contains an additive having an anti-reflective function, and
the additive having an anti-reflective function comprises at least one selected from the group consisting of a compound having an anthracene structure, a compound having an anthraquinone structure, and a compound having a thioxanthone structure.

10. The method of manufacturing a liquid ejection head according to claim 9, wherein a content of the gallate-based photoacid generator contained in the photosensitive resin composition (1) is at least three times as much as a content of the additive having the anti-reflective function.

11. The method of manufacturing a liquid ejection head according to claim 9, wherein a content of the additive having the anti-reflective function is 0.05 parts by mass to 5.0 parts by mass with respect to 100 parts by mass of the epoxy resin.

12. The method of manufacturing a liquid ejection head according to claim 1, wherein the photosensitive resin composition (1) and the photosensitive resin composition (2) contain either a basic substance or a weakly acidic (pKa=−1.5 to 3.0) acid generator.

13. The method of manufacturing a liquid ejection head according to claim 1, wherein the photosensitive resin composition (1) contains a silane coupling agent.

14. The method of manufacturing a liquid ejection head according to claim 1, wherein the photosensitive resin composition (1) contains a polyhydric alcohol.

15. The method of manufacturing a liquid ejection head according to claim 14, wherein the polyhydric alcohol has two or three hydroxyl groups at a terminal and has a repeated structure in a molecule.

16. The method of manufacturing a liquid ejection head according to claim 14, wherein a content of the polyhydric alcohol in the photosensitive resin composition (1) is 0.5 parts by mass to 30.0 parts by mass with respect to 100 parts by mass of the epoxy resin.

17. A liquid ejection head comprising, on a substrate:
an ejection port formation member that forms an ejection port for ejecting a liquid; and
a flow path formation member that forms a flow path that communicates with the ejection port, wherein
the flow path formation member is a cured article of a photosensitive resin composition (1),
the ejection port formation member is a cured article of a photosensitive resin composition (2), and
the photosensitive resin composition (1) contains
at least one epoxy resin selected from the group consisting of an epoxy resin having an aromatic ring and an alicyclic epoxy resin, and
a gallate-based photoacid generator having a salt structure represented by Formula (1) below and having a molar extinction coefficient of at least 0.10 L/mol·cm at a wavelength of 365 nm: 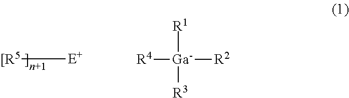
In Formula (1), R¹ to R⁴ are each independently an alkyl group having 1 to 18 carbon atoms or Ar, and at least one of the R¹ to R⁴ is Ar; the Ar is an aryl group having 6 to 14 carbon atoms (the number of carbon atoms of following substituents is not included), and some of hydrogen atoms in the aryl group may be substituted by an alkyl group having 1 to 18 carbon atoms, an alkyl group having 1 to 8 carbon atoms with a halogen atom substituted, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or an aryloxy group represented as —OR⁶, an acyl group represented as R⁷CO—, an acyloxy group represented as R⁸COO—, an alkylthio group or an arylthio group represented as —SR⁹, an amino group represented as —NR¹⁰R¹¹, or a halogen atom; the R⁶ to R⁹ are each independently an alkyl group having 1 to 8 carbon atoms or an aryl group having 6 to 14 carbon atoms, and R¹⁰ and R¹¹ are each independently a hydrogen atom, an alkyl group having 1 to 8 carbon atoms, or an aryl group having 6 to 14 carbon atoms; E represents an element with a valence n from Group 15 to Group 17 (IUPAC nomenclature), n being an integer of 1 to 3, R⁵ is an organic group bonded to E; the number of R⁵ is n+1, (n+1) R⁵ are allowed to be the same or differ from each other, and at least 2 R⁵ are allowed to form a cyclic structure including the element E directly thereamong or via O—, —S—, —SO—, —SO₂—, —NH—, —CO—, —COO—, —CONH—, an alkylene group, or a phenylene group.

18. The liquid ejection head according to claim 17, wherein
a light absorbance of a layer of the photosensitive resin composition (1) per film thickness of 1 μm at the wavelength of 365 nm is at least 0.01 abs/μm, and
a light absorbance of a layer of the photosensitive resin composition (2) per film thickness of 1 μm at the wavelength of 365 nm is at least 0.01 abs/μm.

19. The liquid ejection head according to claim 17, wherein a cationic moiety represented as [R⁵]ₙ₊₁-E⁺ in Formula (1) above is a sulfonium-based cationic moiety.

20. The liquid ejection head according to claim 17, wherein an inorganic material layer is comprised between the substrate and the flow path formation member.
